(19) United States
(12) Patent Application Publication
(10) Pub. No.: US 2005/0133891 A1
(43) Pub. Date: Jun. 23, 2005

(54) System and method for increasing the ball pitch of an electronic circuit package

(75) Inventors: Masud Beroz, Livermore, CA (US); Belgacem Haba, San Jose, CA (US)

Correspondence Address: STEVENS LAW GROUP, P.O. BOX 1667, SAN JOSE, CA, 95109, US

(73) Assignee: Tessera, Inc., San Jose, CA (US)

(21) Appl. No.: 11/013,744

(22) Filed: Dec. 15, 2004

Related U.S. Application Data
(60) Provisional application No. 60/532,339, filed on Dec. 23, 2003.

(51) Int. Cl. H01L 21/44; H01L 23/495

(52) U.S. Cl. 257/673; 438/123; 257/674; 257/676

(57) ABSTRACT

The invention provides an electronic package comprising a die bonded to a substrate, where the die has a fine pitch and the substrate has a coarse pitch. The dies and the substrate each have a plurality of individual lead frame interconnect arrays, with one end of an interconnect bonded to the die at a die pad and another end of the interconnect bonded to the substrate at a substrate pad. The substrate interconnect pads have a greater pitch then the die interconnect pads.

### PRIOR APPLICATION

This application claims priority from U.S. Provisional Patent Application No. 60/532,339 filed Dec. 23, 2003.

### BACKGROUND

The invention is directed to system and method for increasing the ball pitch of an electronic circuit package. Current trends call for increasingly restrictive chip design rules that call for the chip size to decrease, while designs also require the number of connections to the chips to stay the same or increase. Thus, as chip size decreases and connections stay the same or increase, problems persist in making connections to outside circuits. Conventional solutions are usually directed to modifications of wire bonding between the chip and the board or prepackaging of the chip with expanded pitches for later assembly on the board. These methods are inadequate to address such problems, particularly as chip designs evolve. As will be seen, the invention addresses these problems to provide solutions to conform to restrictive chip design rules in an elegant manner.

### SUMMARY OF THE INVENTION

The invention provides an electronic package comprising a die bonded to a substrate, where the die has a fine pitch and the substrate has a coarse pitch. The dies and the substrate each have a plurality of individual lead frame interconnect arrays, with one end of an interconnect bonded to the die at a die pad and another end of the interconnect bonded to the substrate at a substrate pad. The substrate interconnect pads have a greater pitch then the die interconnect pads.

In one embodiment the electronic package further comprises solder ball interconnects at the substrate pad. In a preferred embodiment the substrate interconnect pads have a pitch several times greater then the pitch of the die interconnect pads. The interconnect pads allows for the use of a relatively reduced resolution pitch pad.

### THE FIGURES

FIG. 1 illustrates a portion of a wafer assembly that can be applied to a whole wafer. The assembly includes an array mounted on a SAW green tape 104 where the array is made up of individual die indicated by divider lines.

FIG. 2A illustrates a diced array dividing the die into three sets of three die.

FIG. 2B illustrates a top view of the assembly of FIG. 2A is having sub-arrays separated and mounted on tape.

FIG. 3 illustrates an assembly with the tape having dies mounted thereon. As shown in the Figure a lead frame is mounted on the die as a solder or other conductive media, and is configured to interconnect the exposed leads of the die. The lead frame could be replaced with a flex tape or any other similar substrate. The lead frame includes connected ends that are connected to the die pads, and unconnected ends which are left open for outside connection in a later process. Other interconnects are left connected until after dicing.

FIG. 4 illustrates an assembly with the sub-arrays mounted on tape and having interconnects connected to solder balls mounted thereon. As shown the bond pads are offset by interconnects and the solder balls provide a wider array of connections for the individual dies after they are separated.

FIG. 5A, illustrates a top view of the die assemblies mounted on tape and having the lead frame mounted on the dies. Solder balls are shown positioned on the unconnected connections of the lead frame for connection to an outside media, such as a printed wiring board (PWB) (not shown). The assembly is divisible at dividing lines which are later cut through upon dicing, where the interconnects are later removed.

FIG. 5B illustrates a top view of the assembly of FIG. 5A illustrating separate sub-assemblies with solder balls mounted thereon.

FIG. 6A illustrates an individual die after dicing, where the die chip has interconnects mounted thereon, and solder balls mounted on the free end of the interconnect, where the other end is mounted and electrically connected to the die through bonding pads (not shown).

FIG. 6B illustrates a side view of the die of FIG. 6A. As shown, the pitch expansion could be at least twice or even larger than the original pitch.

FIG. 7 illustrates a flow chart where a substrate is provided, pre-diced and scored, and a sacrificial material (as a mask) is deposited on the substrate and patterned. One or more current leads are deposited, and the dies then separated.

### DESCRIPTION OF THE INVENTION

The invention offers a solution to expand pitch on a die with a means for extending existing wire bond pads outside the direct connection on a surface of the chip. In one embodiment, this is done by way of an extended tab having a conductive connection at its end. Without the invention, it would be difficult to attach die onto a board according to restrictive design rules. Generally, the invention is directed to enlarging the ball pitch at wafer level by extending the location of connection between the chip and the board. Furthermore, the invention provides the ability to alleviate the demand for a higher resolution pad pitch on an FR4 board of the package.

As can be seen, in an illustrative case the entire structure consists of two parts: a die and a substrate. Where the electrical interconnects on the substrate are fanning away from a fine pitch, that this the pitch of the die, to a coarser pitch, The fine pitch corresponds to the die pad pitch, while the coarser pitch could be any pitch depending on particular substrate or package design.

Consider a hypothetical case where a die is to be mounted on a pad with a pad pitch of 100 microns and a spacing of 10 microns between each pad, where the design rules are for a PWB with 100 microns lines and spacing. A pad pitch of 100 micron is pushing the capabilities of the state of the art PWB manufacturing. In order to accommodate flip chipping a die with smaller pad pitch, the die first must be packaged and placed individually on a secondary substrate.

As described herein the die pad pitch is expanded at the wafer level, without increasing actual footprint of the die, and then directly could be picked and placed on conventional, relatively cheaper PWB. This is because PWB-s with coarser pitch are cheaper to manufacture.

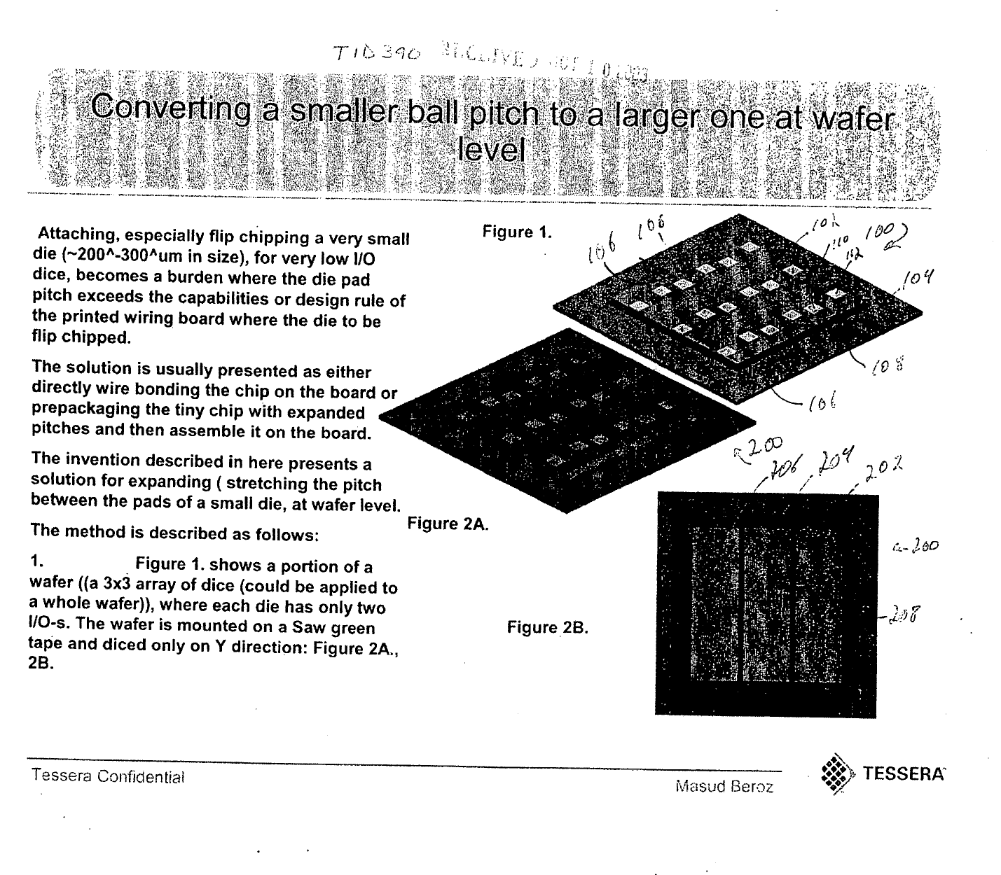

For example, attaching, by flip chip or other process, a very small die (˜200\hat{ }-300\hat{ }um in size), for very low I/O dice, becomes a burden where the die pad pitch exceeds the limits of modern design rule limitations of the printed wiring boards. This is particularly true where the die is configured to be flip chip attached to a wiring board. Conventional solutions are usually directed to either directly wire bonding the chip onto the board, or prepackaging the tiny chip with expanded pitches for later assembly on the board. The invention presents a novel solution for expanding or stretching the pitch between the pads of a small die at wafer level. Referring to FIG. 1, a portion of a wafer assembly 100, shown here as a 3×3 array of dice that could be applied to a whole wafer. The assembly includes an array 102 mounted on a SAW green tape 104. The array is made up of individual die indicated by divider lines 106. Individual die 108, like the other dies in this example, has only two input/output contacts (I/O's) 110, 112. Referring to FIG. 2A, the array 200 is shown diced along one direction, dividing the die into three sets of 3 die. In FIG. 2B, a top view of the assembly 200 of FIG. 2A is shown having sub-arrays 202, 204, 206 separated and mounted on the tape 208.

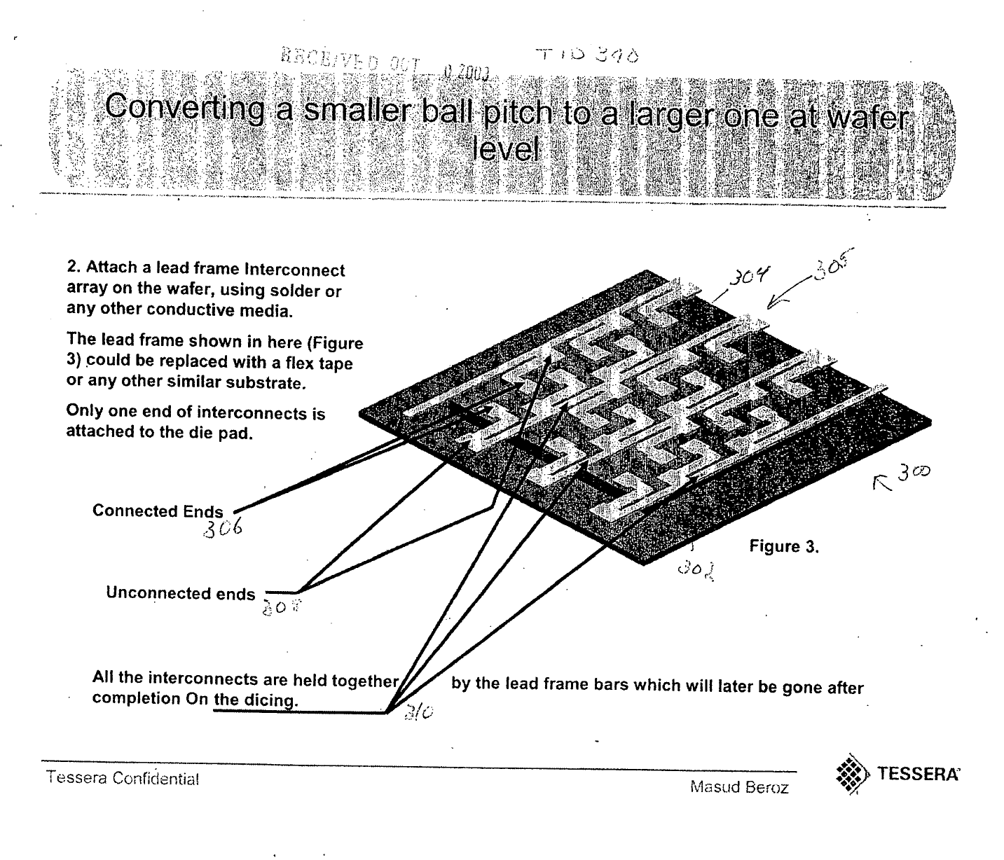

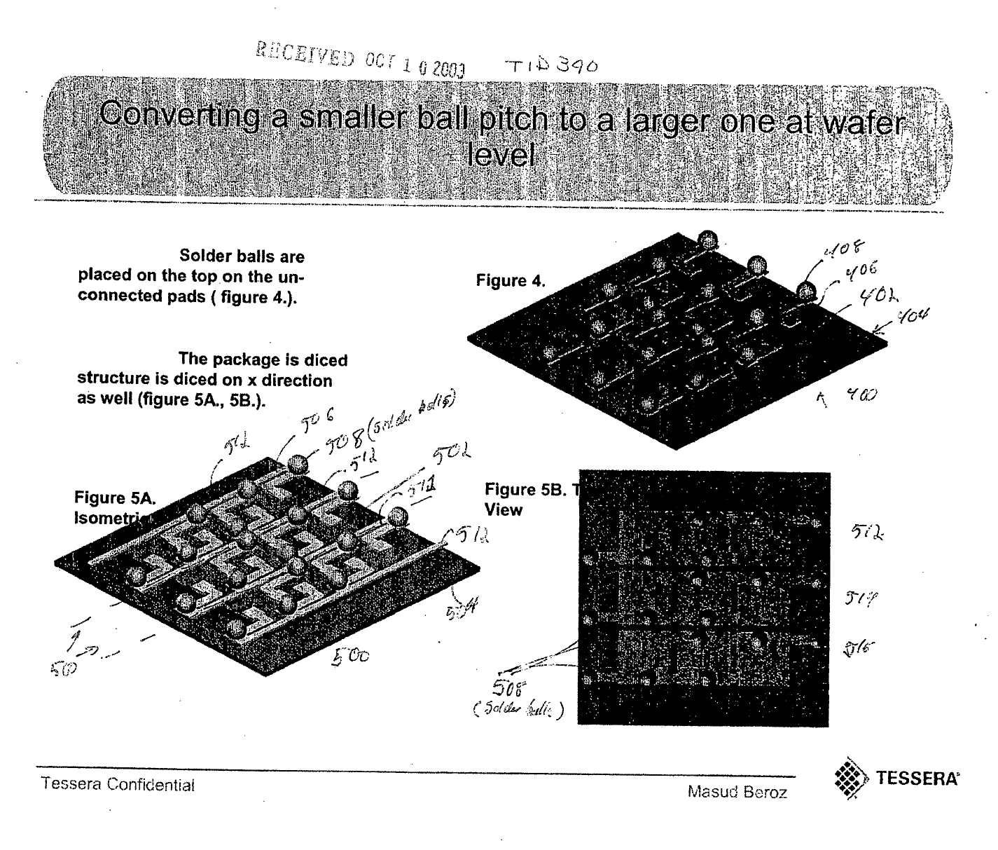

In one embodiment of the invention, a lead frame interconnect array is attached onto a wafer, using solder or any other conductive media. Referring to FIG. 3, an assembly 300 is shown with the tape having the dies 304 mounted thereon. A lead frame 305 is mounted on the die as a solder or other conductive media, and is configured to interconnect the exposed leads of the die. The lead frame shown in FIG. 3 could also be replaced with a flex tape or any other similar substrate. The lead frame includes connected ends 306 that are connected to the die pads, and unconnected ends 308, which are left open for outside connection in a later process. The interconnects 310 are left connected until after dicing. According to the invention, the unconnected ends are left for solder pads to be connected, as shown in FIG. 4.

Referring to FIG. 4, the assembly 400 is shown with the sub-arrays 402 mounted on the tape 404, and having interconnects 406 connected to solder balls 408 mounted thereon. As can be seen, and according to the invention, the bond pads as leads are offset by the interconnects 406, and the solder balls 408 provide a wider array of connections for the individual dies after they are separated.

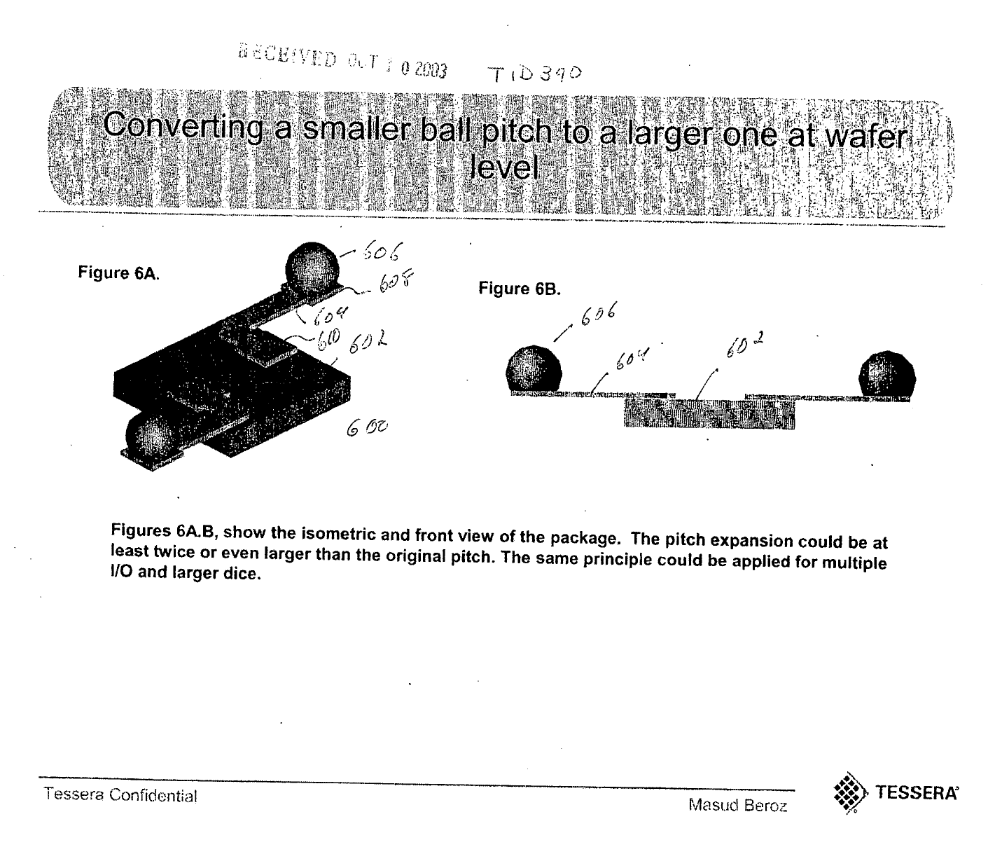

Referring to FIG. 5A, a top view of a the die assemblies 502 mounted on tape 504 is illustrated having the lead frame 506 mounted on the dies. Solder balls are shown positioned on the unconnected connections of the lead frame for connection to an outside media, such as a printed wiring board (PWB) (not shown). The assembly is divisible at dividing lines 510, which are later cut through upon dicing, where the interconnects 511 are later removed. Referring to FIG. 5B, a top view of the assembly of FIG. 5A is shown, illustrating the separate sub-assemblies 512, 514, 516 are illustrated with solder balls 508 mounted thereon. Referring to FIG. 6A, an individual die 600 is illustrated after dicing. The die chip 602 has interconnects 604 mounted thereon, and solder balls 606 mounted on the free end 608 of the interconnect, where the other end 610 is mounted and electrically connected to the die 602 through bonding pads (not shown). FIG. 6B shows a side view of the die of FIG. 6A. As can be seen, the pitch expansion could be at least twice or even larger than the original pitch. The invention can be extended so that the interconnects can be applied to applications with multiple I/O's and larger dice, or other configuration where interconnection of the individual dies with outside media is problematic, where outside connections are to numerous to handle for a given chip size.

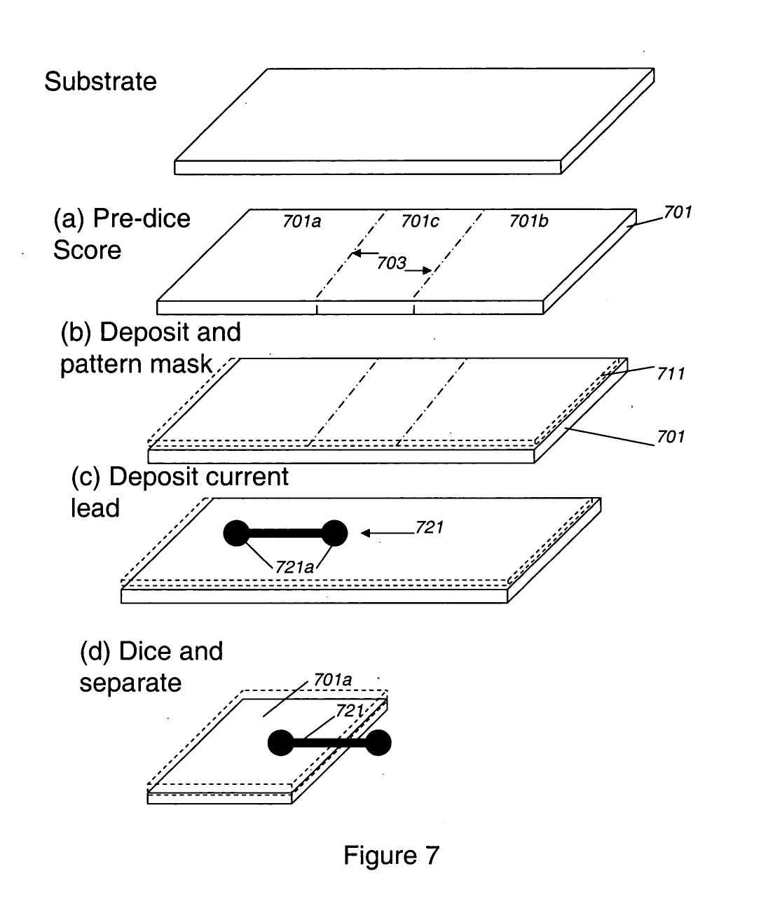

FIG. 7 illustrates a flow chart where a substrate is provided, prediced and scored, with a sacrificial material (as a mask) deposited on the substrate and patterned. One or more current leads are deposited, and the dies then separated.

Specifically, FIG. 7 illustrates, generally, a method of preparing a plurality of integrated circuit chips from a multi-chip wafer. As shown in FIG. 7, an individual chip 701a and 701b in the wafer has a surrounding sacrificial periphery 701c. As shown at element “a. Predice and Score” in FIG. 7, the wafer 701, has scoring 703 between individual chips 701a and 701b within the wafer 701. The scoring 703 is a result of patterning the multi-chip wafer. This leaves a sacrificial periphery 703c between adjacent in process chips 701a and 701b, around each such chip.

In the next step patterning a sacrificial layer, layer or thin film 711, is deposited or applied above the wafer, as shown in “b. Deposit and Pattern Mask.” This layer or thin film 711, which may be a deposited layer, as a resist layer, or an inorganic layer as an oxide or nitride thin film, or the like, is suitably patterned to allow for electrical contacts or pads 721a and current leads 721 to be deposited on the individual chips 701a and 701b of the wafer 701, as shown in “c. Deposit Current Lead.”

The multi-chip wafer is then circuitized by depositing a conductor atop the sacrificial layer 711 with leads 721 therefrom extending through the sacrificial layer 711 to the integrated circuits of the underlying multi-integrated circuit wafer. After deposit of current leads 721, the wafer 701 is separated into individual chips or dies 701a with current leads 721 extending beyond the individual chips 701a. The multichip wafer is separated into the individual integrated, circuits, for example, ultrasonics. The individual chips are typically on the order of millimeters or less in size, and the resulting circuitized, diced chips are useful as, for example, sensors, rfids, and the like.

It is important that the bond of the sacrificial layer 711, that is, the dielectric or mask (which terms are used equivalently herein) to the die do not result in adhesion of the dielectric layer to a neighboring die during die separation. This is especially important where radiation based (light) separation and release methods are employed.

In a particularly preferred embodiment, leads 721 from each die will extend over neighboring die surfaces but is not bonded to the neighboring die surface.

The invention has been described in the context of extended interconnections that connect at one end to a die, and that extend to another location where a conductor such as a solder ball can be mounted for connection to outside media. The invention, however, can be extended to equivalents where extended interconnections are useful. Such equivalents will be understood as within the spirit and scope of the invention, which is defined by the appended claims and equivalents.

1. An electronic package comprising a die bonded to a substrate, said die having a fine pitch and said substrate having a coarse pitch, said die and said substrate having a plurality of individual lead frame interconnect arrays, one end of an interconnect bonded to the die at a die pad and another end of the interconnect bonded to the substrate at a substrate pad, the substrate interconnect pads having a greater pitch then the die interconnect pads.

2. The electronic package of claim 1 further comprising solder ball interconnects at the substrate pad.

3. A package according to claim 1, wherein the interconnect pads allows for the use of a relatively reduced resolution pitch pad.

4. A method of preparing an integrated circuit chip from a multi-chip wafer where an individual chip in the wafer has a surrounding sacrificial periphery, comprising the steps of:
patterning the multi-chip wafer;
depositing a sacrificial layer atop the multi-chip wafer;
patterning the sacrificial layer;
depositing a conductor atop the sacrificial layer with leads therefrom extending through the sacrificial layer to integrated circuits of the underlying integrated circuit;
separating the multichip wafer into individual integrated circuits.

5. The method of claim 4 comprising applying ultrasonic energy to the multichip wafer to separate the said multichip wafer into individual integrated circuit chips.
